(19) United States
(12) Patent Application Publication
(10) Pub. No.: US 2024/0186279 A1
(43) Pub. Date: Jun. 6, 2024

(54) IN-SITU UV CURE PLACEMENT TOOL FOR ROOM TEMPERATURE CHIP/GLASS DEVICE ATTACHMENT

(71) Applicant: Intel Corporation, Santa Clara, CA (US)

(72) Inventors: Minglu LIU, Chandler, AZ (US); Yosuke KANAOKA, Chandler, AZ (US); Jung Kyu HAN, Chandler, AZ (US); Gang DUAN, Chandler, AZ (US); Ziyin LIN, Chandler, AZ (US)

(21) Appl. No.: 18/060,577

(22) Filed: Dec. 1, 2022

(51) Int. Cl. H01L 23/00; B32B 37/12

(52) U.S. Cl. CPC H01L 24/75; B32B 37/12; H01L 24/29; H01L 24/32; H01L 24/83; H01L 2224/2919; H01L 2224/29191; H01L 2224/32225; H01L 2224/75251; H01L 2224/75252; H01L 2224/7531; H01L 2224/83191; H01L 2224/83193; H01L 2224/83874; H01L 2924/0635; H01L 2924/0665; H01L 2924/069; H01L 2924/0715

(57) ABSTRACT

The present disclosure relates to a system. The system may include a stage configured to support a substrate. The system may also include a bondhead configured to press a device against the substrate. The system may further include a light source configured to emit UV light towards the stage.

### BACKGROUND

For semiconductor chip/glass device attachment, high placement accuracy is desired to reduce yield loss or reliability issue for electrical interconnections and reduce signal loss for optical interconnections. In adhesive-based attachment process, thermal adhesive is widely adopted, which involves heating during placement, and post thermal cure can also induce additional post-placement shift.

Ultraviolet (UV) adhesive is also used in certain cases, but UV cure is done in a separate, post placement step. This can induce undesirable post-placement shift during the curing process.

In current processes using thermal and UV adhesives, heating and post cure can impact the final placement accuracy.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows a system for chip/glass device attachment on a glass carrier according to an aspect of the present disclosure;

FIG. 2 shows a system for chip/glass device attachment on a glass carrier according to another aspect of the present disclosure;

FIG. 3 shows a system for glass die/device attachment on a substrate panel according to a further aspect of the present disclosure; and

FIG. 4 shows a flow chart illustrating a method for bonding a device to a substrate according to an aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for systems, and various aspects are provided for methods. It will be understood that the basic properties of the systems also hold for the methods and vice versa. Other aspects may be utilized and structural, and logical changes may be made without departing from the scope of the present disclosure. The various aspects are not necessarily mutually exclusive, as some aspects may be combined with one or more other aspects to form new aspects.

As used herein, the singular forms “a”, “an” and “the” include support for plural referents unless the context clearly dictates otherwise.

The terms “top”, “bottom”, and the like used herein and in the claims are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

The present disclosure may be directed to a system or tool, and also a method for enabling in-situ UV cure during placement of various semiconductor components. For example, the system may be used for chip/glass device attachment on a glass carrier. In another example, the system may be used for glass die/device attachment on a substrate panel.

The system and method of the present disclosure may enable in-situ and room temperature alignment and placement, which is key to achieve high placement accuracy. In other words, no heat/thermal treatment may be carried out according to the present disclosure. Post-placement cure step and post-placement shift during the curing process may therefore be eliminated.

The present disclosure relates to a system. The system may include a stage configured to support a substrate, a bondhead configured to press a device against the substrate, and a light source configured to emit UV light towards the stage.

The present disclosure generally further relates to a method. The method may include arranging a UV curable adhesive sandwiched between a substrate and a device to be bonded to the substrate, providing a stage configured to support the substrate and the device, providing a bondhead configured to press the device against the substrate, and emitting a UV light towards the stage to cure the UV curable adhesive.

To more readily understand and put into practical effect the present disclosure, particular aspects will now be described by way of examples and not limitations, and with reference to the drawings. For the sake of brevity, duplicate descriptions of features and properties may be omitted.

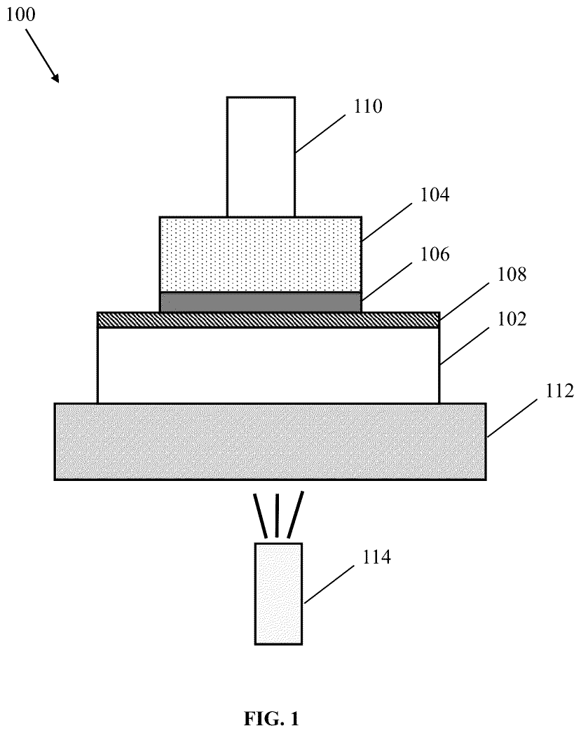

FIG. 1 shows a system for chip/glass device attachment on a glass carrier according to an aspect of the present disclosure.

A system 100 may be provided. The system 100 may include a glass carrier 102 and a chip/glass device 104 to be attached or bonded to the glass carrier 102.

The chip/glass device 104 may include a UV curable adhesive 106 at a surface (i.e., a bonding surface) of the chip/glass device 104 to be bonded to the glass carrier 102. The UV curable adhesive 106 may be pre-formed on the chip/glass device 104. Alternatively, the UV curable adhesive 106 may be formed or deposited on a surface (i.e., a bonding surface) of the glass carrier 102 to be bonded to the chip/glass device 104.

Suitable materials for the UV curable adhesive 106 may include epoxy, acrylic and polyurethane, silicone-based adhesives.

The glass carrier 102 may serve as a temporary support to provide mechanical integrity to the chip/glass device 104 to allow thin device wafer processing. In other words, the glass carrier 102 may be temporarily bonded to the chip/glass device 104 and may subsequently be separated from the chip/glass device 104 with relative ease. To facilitate the ease of removal of the glass carrier 102, a temporary bond debond (TBDB) adhesive 108 may be included on the bonding surface of the glass carrier 102.

Suitable materials for the TBDB adhesive 108 may include silicone, epoxy or polyimide-based adhesives.

The system 100 may also include a bondhead 110. The bondhead 110 may serve to exert a pressure or force on the chip/glass device 104 during the bonding process.

The system 100 may further include a UV transparent stage 112 or supporting platform to support various components described above. In other words, the UV transparent stage 112 may allow UV light to pass through.

In one aspect, the UV transparent stage 112 may include a solid material with high transparency in the UV wavelength. Suitable materials for the solid materials may include UV glass, Acrylic and Quartz.

In another aspect, the UV transparent stage 112 may include a hollow design providing only edge support to the glass carrier 102. The hollow design may allow UV light to pass through.

The system 100 may include a UV source 114, e.g., a UV lamp. The UV source 114 may be configured to provide UV light to the UV curable adhesive 106 to thereby cure it, allowing the chip/glass device 104 to be bonded to the glass carrier 102.

In the aspect shown in FIG. 1, various components of the system 100 may be arranged in the following top-to-bottom manner: bondhead 110, chip/glass device 104, UV curable adhesive 106. TBDB adhesive 108, glass carrier 102, stage 112, and UV source 114. The bondhead 110 may exert a downward force while the UV source 114 may provide UV light in the opposing upward direction.

During the attachment process, the sandwich arrangement of the chip/glass device 104, UV curable adhesive 106, TBDB adhesive 108, and glass carrier 102 may be placed on the stage 112. A low force may be applied through the bondhead 110 to align and hold the various components in place. Final, precise alignment (i.e., planar as well as angular adjustments) may then be carried out by the bondhead 110 prior to the UV exposure from the UV source 114. After the UV curable adhesive has been cured or set, pressure on the various components may be removed by releasing the bondhead 110 away from the components.

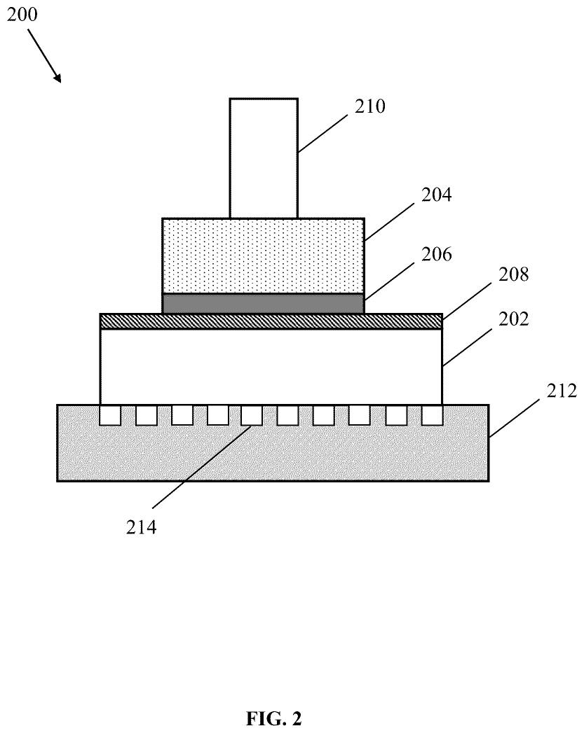

FIG. 2 shows a system for chip/glass device attachment on a glass carrier according to another aspect of the present disclosure.

A system 200 may be provided. The system 200 may include a glass carrier 202 and a chip/glass device 204 to be attached or bonded to the glass carrier 202.

The chip/glass device 204 may include a UV curable adhesive 206 at a surface (i.e., a bonding surface) of the chip/glass device 204 to be bonded to the glass carrier 202. The UV curable adhesive 206 may be pre-formed on the chip/glass device 204. Alternatively, the UV curable adhesive 206 may be formed or deposited on a surface (i.e., a bonding surface) of the glass carrier 202 to be bonded to the chip/glass device 204.

Suitable materials for the UV curable adhesive 206 may include epoxy, acrylic and polyurethane, silicone-based adhesives.

The glass carrier 202 may serve as a temporary support to provide mechanical integrity to the chip/glass device 204 to allow thin device wafer processing. In other words, the glass carrier 202 may be temporarily bonded to the chip/glass device 204 and may subsequently be separated from the chip/glass device 204 with relative case. To facilitate the case of removal of the glass carrier 202, a temporary bond debond (TBDB) adhesive 208 may be included on the bonding surface of the glass carrier 202.

Suitable materials for the TBDB adhesive 208 may include silicone, epoxy or polyimide-based adhesives.

The system 200 may also include a bondhead 210. The bondhead 210 may serve to exert a pressure or force on the chip/glass device 204 during the bonding process.

The system 200 may further include a stage 212 or supporting platform to support various components described above. The stage 212 may be configured to provide a UV source 214, e.g., a UV lamp. The UV source 214 may be configured to provide UV light to the UV curable adhesive 206 to thereby cure it, allowing the chip/glass device 204 to be bonded to the glass carrier 202. In one aspect, the UV source 214 may include an array of UV light source.

In the aspect shown in FIG. 2, the UV source 214 may be embedded in the stage 212. The stage 212 may or may not be a UV transparent stage, depending on the locations of the embedded UV source 214. For example, if the UV source 214 is embedded in the stage 212 but are located close to or at the interface between the stage 212 and the glass carrier 202, the stage 212 may not need to be a UV transparent stage since the UV light may not need to pass through the stage 212.

On the other hand, if the UV source 214 are embedded away from the interface between the stage 212 and the glass carrier 202, then the stage 212 may need to be a UV transparent stage so that UV light may pass through it.

In the aspect shown in FIG. 2, various components of the system 200 may be arranged in the following top-to-bottom manner: bondhead 210, chip/glass device 204, UV curable adhesive 206, TBDB adhesive 208, glass carrier 202, stage 212 including the embedded UV source 214. The bondhead 210 may exert a downward force while the UV source 214 may provide UV light in the opposing upward direction.

During the attachment process, the sandwich arrangement of the chip/glass device 204, UV curable adhesive 206, TBDB adhesive 208, and glass carrier 202 may be placed on the stage 212. A low force may be applied through the bondhead 210 to align and hold the various components in place. Final, precise alignment (i.e., planar as well as angular adjustments) may then be carried out by the bondhead 210 prior to the UV exposure from the UV source 214. After the UV curable adhesive has been cured or set, pressure on the various components may be removed by releasing the bondhead 210 away from the components.

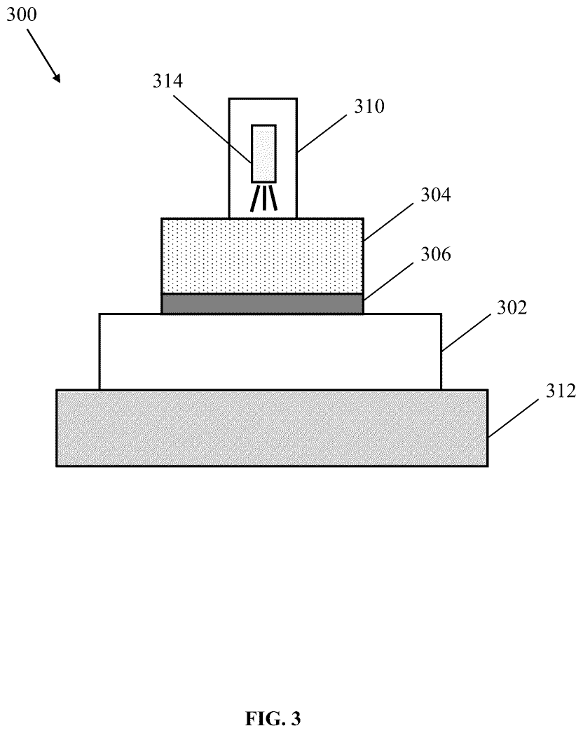

FIG. 3 shows a system for glass die/device attachment on a substrate panel according to a further aspect of the present disclosure.

A system 300 may be provided. The system 300 may include a substrate panel 302 and a glass die/device 304 to be attached or bonded to the substrate panel 302.

The substrate panel 302 may include a semiconductor package substrate, a printed circuit board, or any other semiconductor substrate that may possess sufficient mechanical integrity so that a TBDB adhesive may not be required.

The glass die/device 304 may include a UV curable adhesive 306 at a surface (i.e., a bonding surface) of the glass die/device 304 to be bonded to the substrate panel 302. The UV curable adhesive 306 may be pre-formed on the glass die/device 304. Alternatively, the UV curable adhesive 306 may be formed or deposited on a surface (i.e., a bonding surface) of the substrate panel 302 to be bonded to the glass die/device 304.

Suitable materials for the UV curable adhesive 306 may include epoxy, acrylic and polyurethane, silicone-based adhesives.

The system 300 may also include a bondhead 310. The bondhead 310 may serve to exert a pressure or force on the glass die/device 304 during the bonding process.

The system 300 may further include a stage 312 or supporting platform to support various components described above. The stage 312 may or may not be UV transparent.

The system 300 may include a UV source 314, e.g., a UV lamp. The UV source 314 may be configured to provide UV light to the UV curable adhesive 306 to thereby cure it, allowing the glass die/device 304 to be bonded to the substrate panel 302.

As shown in FIG. 3, the UV source 314 may be integrated with the bondhead 310. For example, the UV source 314 may be located inside the bondhead 310. In this configuration, the bondhead surface and sidewalls may be UV transparent so that UV light from the inside UV source 314 may pass out from the bondhead 310.

In one aspect, the bondhead 310 may include a solid material with high transparency in the UV wavelength. Suitable materials for the solid materials may include UV glass, Acrylic and Quartz.

In another aspect, the bondhead 310 may include a hollow design providing only edge support to hold the glass die/device 304. The hollow design may allow UV light to pass through.

In the aspect shown in FIG. 3, various components of the system 300 may be arranged in the following top-to-bottom manner: bondhead 310 integrated with UV source 314, glass die/device 304, UV curable adhesive 306, substrate panel 302, and stage 312. The bondhead 310 may exert a downward force and the UV source 314 may provide UV light in the same downward direction.

During the attachment process, the sandwich arrangement of the glass die/device 304, UV curable adhesive 106, and substrate panel 302 may be placed on the stage 312. A low force may be applied through the bondhead 310 to align and hold the various components in place. Final, precise alignment (i.e., planar as well as angular adjustments) may then be carried out by the bondhead 310 prior to the UV exposure from the UV source 314. After the UV curable adhesive has been cured or set, pressure on the various components may be removed by releasing the bondhead 310 away from the components.

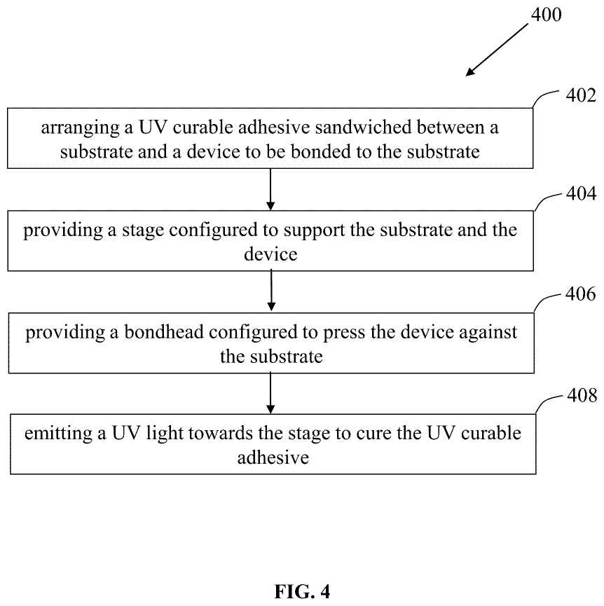

FIG. 4 shows a flow chart illustrating a method for bonding a device to a substrate according to an aspect of the present disclosure.

As shown in FIG. 4, at operation 402, the method 400 may include arranging a UV curable adhesive sandwiched between a substrate and a device to be bonded to the substrate.

At operation 404, the method 400 may include providing a stage configured to support the substrate and the device.

At operation 406, the method 400 may include providing a bondhead configured to press the device against the substrate.

At operation 408, the method 400 may include emitting a UV light towards the stage to cure the UV curable adhesive.

It will be understood that the above operations described above relating to FIG. 4 are not limited to this particular order. Any suitable, modified order of operations may be used.

### EXAMPLES

Example 1 may include a system including a stage configured to support a substrate, a bondhead configured to press a device against the substrate, and a light source configured to emit UV light towards the stage.
Example 2 may include the system of example 1 and/or any other example disclosed herein, wherein the substrate may be UV transparent.
Example 3 may include the system of example 2 and/or any other example disclosed herein, wherein the stage may be UV transparent.
Example 4 may include the system of example 3 and/or any other example disclosed herein, wherein the light source may be located below the stage and configured to emit UV light through the stage.
Example 5 may include the system of example 1 and/or any other example disclosed herein, wherein the stage may include a hollow design with an edge configured to support the substrate and the device.
Example 6 may include the system of example 5 and/or any other example disclosed herein, wherein the light source may be located below the stage and configured to emit UV light through the hollow stage.
Example 7 may include the system of example 1 and/or any other example disclosed herein, wherein the light source may include an array of UV sources embedded in the stage.
Example 8 may include the system of example 1 and/or any other example disclosed herein, wherein the device may be transparent.
Example 9 may include the system of example 8 and/or any other example disclosed herein, wherein the light source may be located inside the bondhead.
Example 10 may include the system of example 9 and/or any other example disclosed herein, wherein the bondhead may be UV transparent.
Example 11 may include a system of example 9 and/or any other example disclosed herein, wherein the bondhead may include a hollow design including an edge configured to press the device against the substrate.
Example 12 may include a method including arranging a UV curable adhesive sandwiched between a substrate and a device to be bonded to the substrate, providing a stage configured to support the substrate and the device, providing a bondhead configured to press the device against the substrate, and emitting a UV light towards the stage to cure the UV curable adhesive.
Example 13 may include the method of example 12 and/or any other example disclosed herein, wherein the substrate may be UV transparent.
Example 14 may include the method of example 13 and/or any other example disclosed herein, wherein the stage may be UV transparent and emitting a UV light may include passing the UV light through the stage and substrate.
Example 15 may include the method of example 13 and/or any other example disclosed herein, wherein the stage may include a hollow design with edge configured to support the substrate and device, and emitting a UV light may include passing the UV light through the hollow stage and substrate.
Example 16 may include the method of example 13 and/or any other example disclosed herein, including embedding an array of UV sources in the stage.
Example 17 may include the method of example 12 and/or any other example disclosed herein, wherein the device may be transparent.
Example 18 may include the method of example 17 and/or any other example disclosed herein, including emitting a UV light from the interior of the bondhead.
Example 19 may include the method of example 18 and/or any other example disclosed herein, wherein the bondhead may be UV transparent.
Example 20 may include the method of example 18 and/or any other example disclosed herein, wherein the bondhead may include a hollow design with edge configured to press the device against the substrate.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

While the present disclosure has been particularly shown and described with reference to specific aspects, it should be understood by persons skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

1. A system comprising:
a stage configured to support a substrate;
a bondhead configured to press a device against the substrate; and
a light source configured to emit UV light towards the stage;
wherein the substrate is UV transparent; and
wherein the stage is UV transparent.

2. (canceled)

3. (canceled)

4. The system of claim 1, wherein the light source is located below the stage and configured to emit UV light through the stage.

5. The system of claim 1, wherein the stage comprises a hollow design with an edge configured to support the substrate and the device.

6. The system of claim 5, wherein the light source is located below the stage and configured to emit UV light through the hollow stage.

7. (canceled)

8. The system of claim 1, wherein the device is transparent.

9. The system of claim 8, wherein the light source is located inside the bondhead.

10. The system of claim 9, wherein the bondhead is UV transparent.

11. The system of claim 9, wherein the bondhead comprises a hollow design including an edge configured to press the device against the substrate.

12. A method comprising:
arranging a UV curable adhesive sandwiched between a substrate and a device to be bonded to the substrate;
providing a stage configured to support the substrate and the device;
providing a bondhead configured to press the device against the substrate; and
emitting a UV light towards the stage to cure the UV curable adhesive;
wherein the stage is UV transparent; and
wherein the light source is located below the stage and configured to emit UV light through the stage.

13. The method of claim 12, wherein the substrate is UV transparent.

14. The method of claim 13, wherein the stage is UV transparent and emitting a UV light comprises passing the UV light through the stage and substrate.

15. The method of claim 13, wherein the stage comprises a hollow design with edge configured to support the substrate and device, and emitting a UV light comprises passing the UV light through the hollow stage and substrate.

16. The method of claim 13, comprising embedding an array of UV sources in the stage.

17. The method of claim 12, wherein the device is transparent.

18. The method of claim 17, comprising emitting a UV light from the interior of the bondhead.

19. The method of claim 18, wherein the bondhead is UV transparent.

20. The method of claim 18, wherein the bondhead comprises a hollow design with edge configured to press the device against the substrate.

21. A system comprising:
a stage configured to support a substrate;
a bondhead configured to press a device against the substrate; and
a light source configured to emit UV light towards the stage;
wherein the light source comprises an array of UV sources embedded in the stage.
